(19) United States
(12) Patent Application Publication
(10) Pub. No.: US 2003/0096194 A1
(43) Pub. Date: May 22, 2003

(54) Silylating process for photoresists in the UV region

(76) Inventors: Jorg Rottstegge, Erlangen (DE); Gertrud Falk, Erlangen (DE); Christian Eschbaumer, Schwaig (DE); Christoph Hohle, Bubenreuth (DE); Michael Sebald, Weisendorf (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 10/177,946

(22) Filed: Jun. 20, 2002

(30) Foreign Application Priority Data
Jun. 20, 2001 (DE) 101 29 577.4

(51) Int. Cl. G03F 7/40

(52) U.S. Cl. 430/311; 430/313

(57) ABSTRACT

The invention relates to a process for consolidating resist structures. It uses a resist that includes a film-forming polymer containing free acidic or basic groups. The amplifying agent used is a compound having a basic group or acidic group complementary to the groups of the film-forming polymer. During the amplifying reaction, the amplifying agent is coordinated to the film-forming polymer by an acid-base reaction in the course of which the amplifying agent and the anchor group of the film-forming polymer form a salt.

### BACKGROUND OF THE INVENTION

### FIELD OF THE INVENTION

The invention relates to a process for consolidating resist structures such as are used in particular in the production of microchips, and to a process for structuring substrates for microelectronic circuits.

The structuring, or patterning, of semiconductor substrates that is a necessary part of microchip production is normally carried out by lithographic techniques. A photosensitive resist layer is applied to the substrate and then an image of the structure of the electronic components is generated in the photoresist by exposing the photoresist using a mask or a focused electron beam. Exposed and unexposed areas of the photoresist differ in their solubility in, say, aqueous-organic polar solvents or organic apolar solvents. In a development step, therefore, it is possible to remove part of the photoresist, corresponding to the exposed or unexposed part, from the substrate to give a structured resist layer which acts as a mask in further process steps: for example, when the substrate is etched in a plasma. In order to increase the sensitivity of the photoresist to the radiation used for exposure, it is nowadays common to use chemically reinforced resists (known as chemically amplified resists, CARs). The photoresist contains on the one hand a polymer that contains, for example, acid-labile groups, and on the other hand a substance that can be activated by light, which on exposure releases, for example, an acid. The acid-labile groups of the film-forming polymer are selected so that they can be eliminated under the catalytic effect of an acid. If, then, the radiation to which the photoacid generator (PAG) is exposed causes it to release a proton, this proton is able to bring about the elimination of a large number of acid-labile groups. As a result of the elimination of the acid-labile groups, usually a polar group, such as a carboxyl group or an acidic phenolic hydroxyl group, for example, is released, leading to a considerable increase in the solubility of the polymer in an aqueous alkaline developer. In order to accelerate the elimination of the protective groups and to obtain a complete reaction, the exposed photoresist is generally heated (PEB: post-exposure bake).

Groups in the polymer that can be cleaved by strong acids include, for example, carboxylic acid tert-alkyl esters, which following cleavage of the tert-alkyl ester are present in the form of free carboxylic acid groups. Further groups which can be eliminated by acid are, for example, tert-butyl, tetrahydrofuranyl, tetrahydropyranyl, acetal or tert-butoxycarbonyl groups.

The structured photoresists serve as a mask for further processes, such as dry etching processes, which are used to structure the substrate—silica, for example—that is disposed beneath the photoresist. The structured photoresist is then required to have a high etch resistance in comparison to the organic or inorganic substrate exposed below it. The etch resistance depends on the nature of the plasma used and of the composition of the resist. For instance, silicon compounds in an oxygen plasma produce highly volatile silicon dioxide. In a fluorine plasma, on the other hand, volatile silicon tetrafluoride is produced. Even if a very selective plasma etching process is chosen for substrate structuring, with the structured resist layer treated gently at the same time, the dry etch resistance of the resist is often not high enough to allow sufficiently deep structures to be etched into the substrate. In this case, chemical consolidation or after-treatment of the structured resist with dry-etch-resistant chemicals is necessary in order to increase the etch resistance of the resist. Where the substrate to be structured in the dry etching process is an organic-chemical layer which is silicon-free, as in the case of multilayer resist structures, for example, the etch resistance of the top resist layer in an oxygen plasma can be increased markedly by the subsequent incorporation of organosilicon compounds into the structure of the resist. The reaction by which the silicon-containing groups are incorporated into the resist is normally termed silylation. Silylation may take place either from the gas phase or from solution.

Issued European Patent EP 0 395 917 B1describes a process for amplifying structured resists. The resist includes a polymer containing carboxylic anhydride groups in its molecular framework. The resist is applied to the substrate to be structured and is dried in a subsequent heating step, in which the solvent is able to evaporate, at a temperature of from 80 to 160° C. A latent image of the desired structure is then produced in the solid resist film by selective irradiation using a photomask or by direct irradiation with focused electrons or ions. The image contains, in the exposed areas, the acid generated from the photoacid generator. In a heating step following exposure, the catalytic effect of the acid generated by exposure causes elimination of the functional protective groups on the polymer. In the exposed areas, therefore, the resist film becomes soluble in an alkaline developer. In the subsequent developing step, which is effected by treating the resist film with, for example, a 2.38% strength solution of tetramethylammonium hydroxide in water, the exposed areas are dissolved away to give a positive relief pattern in the resist film. At the exposed areas the substrate is bare, whereas the unexposed areas are still protected by the solid resist film. Direct silylation with the silylating solution is possible on the remaining anhydride groups of the resist, which is now structured. The silylating solution contains, for example, a bisaminosiloxane. The amino groups react with the anhydride groups of the polymer which is present in the structured resist. A crosslinking reaction takes place to form acid amides. Finally, the product is washed with an-appropriate washing solution.

This amplification process still has a number of disadvantages. The acid anhydride groups present in resist polymers are highly reactive toward water. The resist is therefore susceptible to decomposition by water. Increasing decomposition of the resist is also accompanied, however, by drastic changes in the silylating behavior of the resist layers. Accordingly, the reaction times are no longer reproducible and fluctuations are observed in the production process, which may be so severe that they lead to failures in the fabricated microchip.

The high reactivity of the acid anhydride groups contained in the film-forming polymer toward water requires compliance with water-free conditions during preparation of the polymer and/or the photoresist in order for the photoresist to have satisfactory stability on storage. For the processing of the resist as well, i.e., for the generation and structuring of the resist layers, the absence of water as far as possible is required. Moreover, the silylating reaction often proceeds only at a low rate. In order to be able to carry out the silylating of the structures at a sufficient speed after the resist has been structured, it is necessary in addition to raise the solubility of the polymer present in the resist, which is a complex operation, involving deliberate partial decomposition of the anhydride groups, for instance. Moreover, high concentrations of organosilicon compounds are sometimes required in order to achieve a technically realizable, short reaction time in the production process. Silylation and, together with it, the increase in layer thickness have to date been controlled by way of the increasing solubility of the polymer in polar solvents, such as in the basic developer, which proceeds in parallel with the increasing silylation rate. Another disadvantage of the process which has been customary to date is that the acid anhydride groups of the polymer which are required for attachment of the silylating reagent exhibit high absorption at short wavelengths. In order to be able to image extremely small structures, shorter and shorter wavelengths are being used in lithographic techniques. Because of the high absorption of exposure radiation with a wavelength of, for example, 157 nm in the photoresist, it is possible only to process photoresist layers having a thickness of less than 50 nm. Such thin resist layers require amplification after structuring, by increasing their layer thickness, for example, in order to allow satisfactory results to be achieved in the subsequent etching steps.

### SUMMARY OF THE INVENTION

It is accordingly an object of the invention to provide a process for consolidating resist structures which overcomes the above-mentioned disadvantages of the prior art methods of this general type.

In particular, it is an object of the invention to provide a process for consolidating resist structures that can be carried out more quickly and more easily than the existing processes.

With the foregoing and other objects in view there is provided, in accordance with the invention, a process for consolidating resist structures that includes the following steps:

(a) providing a chemically amplified resist including:

a polymer including acid-labile groups which on exposure to an acid are eliminated and release a group that results in an increase in a solubility of the polymer in aqueous alkaline developers, the polymer further including at least one anchor group for coordinating amplifying agents,

a photoacid generator, and

a solvent;

(b) applying the chemically amplified resist to a substrate;

(c) drying the resist to give a dried resist;

(d) exposing the dried resist to obtain an exposed resist that contains a latent image;

(e) heating the exposed resist to a first temperature such that the latent image is transformed into a chemical profile;

(f) developing the resist with an aqueous alkaline developer such that areas formed by the chemical profile are detached from the substrate and such that a structured resist is obtained;

(g) applying an amplifying agent to the structured resist; and

(h) washing off excess amplifying agent.

The amplifying agent and the anchor group each include a polar group or an ionic group. The coordination of the amplifying agent onto the anchor group takes place with the formation of a noncovalent bond.

In accordance with an added feature of the invention, the at least one anchor group is a protected anchor group including a first anchor group; and before, performing step (g), the first anchor group is released from the protected anchor group;

In accordance with additional feature of the invention, the amplifying agent and the anchor group form an acid-base pairing and the amplifying agent is coordinated to the anchor group by forming a salt through an acid-base reaction.

In accordance with another feature of the invention, the anchor group is a Brönsted base and the amplifying agent is a Brönsted acid.

In accordance with a further feature of the invention, the anchor group is an amino group that is protected by an acid-labile group.

In accordance with a further added feature of the invention, the anchor group is a Brbnsted acid and the amplifying agent is a Brönsted base.

In accordance with a further additional feature of the invention, the anchor group is a carboxyl group, a sulfonic acid group, an acidic phenolic hydroxyl group and/or an acidic alcoholic hydroxyl group.

In accordance with yet an added feature of the invention, the amplifying agent is a silicon compound with a basic functionalization.

In accordance with yet an additional feature of the invention, the amplifying agent is applied, as a solution, to the structured resist.

In accordance with yet another feature of the invention, the structured resist is subjected to flood exposure and is then heated.

In accordance with yet a further feature of the invention, the resist is provided with a thermoacid generator releasing an acid at a second temperature that is higher than the first temperature; and the structured resist is heated to the second temperature.

With the foregoing and other objects in view there is provided, in accordance with the invention, a process for structuring a substrate for a microelectronic circuit. The process includes steps of:

(a) providing a chemically amplified resist including:

a polymer including acid-labile groups which on exposure to an acid are eliminated and release a group that results in an increase in a solubility of the polymer in aqueous alkaline developers, the polymer further including at least one anchor group for coordinating amplifying agents,

a photoacid generator, and

a solvent;

(b) applying the chemically amplified resist to the substrate;

(c) drying the resist to give a dried resist;

(d) exposing the dried resist to obtain an exposed resist that contains a latent image;

(e) heating the exposed resist to a first temperature such that the latent image is transformed into a chemical profile;

(f) developing the resist with an aqueous alkaline developer such that areas formed by the chemical profile are detached from the substrate and such that a structured resist is obtained;

(g) applying an amplifying agent to the structured resist;

(h) washing off excess amplifying agent; and

(i) then etching the substrate.

The amplifying agent and the anchor group each include a polar group or an ionic group. The coordination of the amplifying agent onto the anchor group takes place by forming a noncovalent bond.

In accordance with an added feature of the invention, the resist is amplified with a silicon-containing amplifying agent; and the step of etching the substrate is performed using an oxygen plasma.

### DESCRIPTION OF THE PREFERRED EMBODIMENTS

In the inventive process, the attachment of the amplifying agent takes place not by a nucleophilic attack by a group of the amplifying agent on the carbonyl carbon of the carboxylic anhydride group to form a covalent bond, but instead by coordination of the amplifying agent to the anchor group by means of relatively weak bonding forces. For this to be so, the anchor group and the amplifying agent must be of sufficient polarity to allow fixing of the amplifying agent on the anchor group. The amplifying agent and/or the anchor group must also suitably possess a sufficiently high polarity to allow coordination by dipole-dipole interactions. Both groups may have a corresponding permanent dipole moment, or one of the reactants may have a permanent dipole moment which induces a corresponding dipole moment in the other reactant. The other reactant must also be sufficiently polarizable. In addition, at least one of the reactants may be in ionic form, and the coordination may take place by ionic interaction or by interaction of the ionic reactant with the other reactant which possesses a permanent or induced dipole moment.

Coordination of the amplifying agent to the anchor group takes place preferably by means of an acid-base reaction, in which a proton passes from the acid group to a corresponding basic group. A neutralization reaction of this type generally takes place very fast. Its product is normally salts. In a reaction following the neutralization, however, it is also possible for covalent bonds to be formed, with acid amide bonds being formed, for example, with the elimination of water. In this case, one of the reactants contains an amino group and the other a carboxyl group. Coordination takes place first of all, in accordance with the invention, by salt formation, with the amino group being protonated and the carboxyl group being deprotonated. In other words, attachment takes place through a noncovalent bond. In a later process step, in which the resist is heated for the purpose of drying, for example, attachment of the amplifying agent to the anchor group via a covalent bond can then take place with the formation of an amide group.

For the attachment of the amplifying agent, the polymers used in the process must no longer contain any carboxylic anhydride groups. Both the polymer and the resist produced from the polymer, therefore, are no longer sensitive toward water. Since the ingress of water need no longer be prevented, therefore, processing and storage are made significantly easier. In particular, there is no need as hitherto for the polymer to be dried.

Since the coordination of the amplifying agent to the anchor group, utilized in the process of the invention, takes place by way of noncovalent bonds, taking the form, for example, of a neutralization reaction, and normally proceeds much more quickly than the opening of an anhydride, it is possible to accelerate the amplification process or to use a lower concentration of amplifying agent in the amplifying solution. A rapid and complete reaction is advantageous especially in the case of thin resists, for which the resistance to dry etching must be increased to a particularly great extent. Because of the low layer thickness, it was hitherto possible here only to use resists featuring low solubility of the unexposed areas in the aqueous developer medium. In this case, therefore, the rate of the amplification reaction is very low. Such thin resist layers are used, for example, for lithographic techniques where exposure is carried out using radiation with a wavelength of 157 nm.

Polymers which can be used as film formers are all polymers possessing, in the chain or independently, acid-labile groups of low alkali solubility which by catalytic exposure to acid, and where appropriate, simultaneous temperature treatment, produce alkali-soluble groups on the polymer. Suitable examples include the following acid-labile groups: tert-alkyl ester, tert-butoxycarbonyloxy, tetrahydrofuranyl, tetrahydropyranyl, tert-butyl ether, lactone, and acetyl groups. Preference is given to using tert-butyl ester groups.

Preferred anchor groups in the polymer are those groups which bring about increased transparency of the polymers, and thus of the resist layer, to light with a very short wavelength of, for example, 157 nm. One preferred example are 1,1,1,3,3,3-hexafluoro-2-hydroxyisopropyl groups, where the hydroxyl group has been protected by a tert-butyl ether, tert-butoxycarbonyloxy, tetrahydrofuranyl, tetrahydropyranyl or acetal radical or by another acid-eliminable radical.

The film-forming polymer may also contain further groups which enhance the lithographic properties of the resist, or its etch resistance. Reactive groups as well, such as succinic anhydride groups and esters functionalized with acid-labile groups, may also be present in the polymer in order to allow a subsequent chemical treatment of the resist structures.

As photoacid generators it is possible to use any compounds which release acid on irradiation. It is advantageous to use onium compounds, such as those described, for example, in EP 0 955 562 A1.

Examples of resist solvents which can be used include methoxypropyl acetate, cyclopentanone, cyclohexanone, γ-butyrolactone, ethyl lactate, diethylene glycol diethyl ether, diethylene glycol dimethyl ether or a mixture of at least two of these compounds. In general, however, all common solvents or mixtures thereof can be used that are capable of taking up resist components in a clear, homogeneous, and storage-stable solution and which ensure good film quality when the substrate is coated.

The resist generally has the following composition:

Film-forming polymer: from 1 to 50% by weight, preferably from 2 to 10% by weight;

Photoacid generator: from 0.01 to 10% by weight, preferably from 0.1 to 1% by weight;

Solvent: from 50 to 99% by weight, preferably from 88 to 97% by weight.

In addition to the compounds mentioned, the photoresist may also include further components. By way of example, additives may be present which increase the quantum yield when the acid is released. Additives may also be added which influence the resist system advantageously in respect of resolution, film-forming properties, stability on storage, service life effect, etc. Such additives are known to the skilled worker.

In multilayer resists the process may also be used to amplify the top resist, where first of all a first resist layer is applied to the substrate and then a further, photoactivatable resist layer, with which the resist is structured, is applied atop the first resist layer.

Following exposure and development, the substrate is bare at the exposed areas, while the unexposed areas are still protected by the solid resist film. Where the remaining resist, which is now structured, already contains groups able to act as anchor groups for the coordination of the amplifying agent, direct amplification of the resist with an amplifying solution is possible. Where the resist does not possess any anchor groups, the structured resist can be functionalized for subsequent amplification in a variety of ways. Where the resist includes a thermoacid generator in addition to the components already described, the acid-labile protective groups are now also eliminated in the previously unexposed areas in a subsequent thermal step, in the course of which the structured photoresist is heated to a temperature which lies above that of the thermal treatment steps carried out hitherto. An alternative option is flood exposure with subsequent heating of the exposed resist. By this means the acid-labile groups as well are eliminated in the structured resist, so that anchor groups are created for the coordination of the amplifying agent.

Prior to further processing of the structured and amplified resist, excess amplifying agent is removed generally by washing off, with water or propanol, for example.

In one first embodiment of the process, the anchor group is a Brönsted acid and the amplifying agent is a Brönsted base. In this embodiment, therefore, the molecular framework of the film-forming polymer carries acidic groups, such as carboxyl groups, acidic phenolic hydroxyl groups and/or acidic alcoholic hydroxyl groups, for example. Preferably, an acid-labile group is attached to the carboxyl group, the acidic phenolic hydroxyl group and/or the acidic alcoholic hydroxyl group by way of an ester or ether linkage. Coordination of the amplifying agent takes place in this case following the elimination of the acid-labile groups.

The polymer is generally composed of at least two different polymer building blocks (monomer units). Shown below is a selection of suitable monomer units which have an anchor group which is a Bronsted acid. Y stands for a hydrogen atom or an acid-labile group and n stands for 0, 1, 2 or 3. Acid-labile groups Y which can be used include, for example, the groups already mentioned above. R¹ stands for any group which is not acid-labile, preferably for an alkyl radical, which may preferably contain from 1 to 10 carbon atoms.

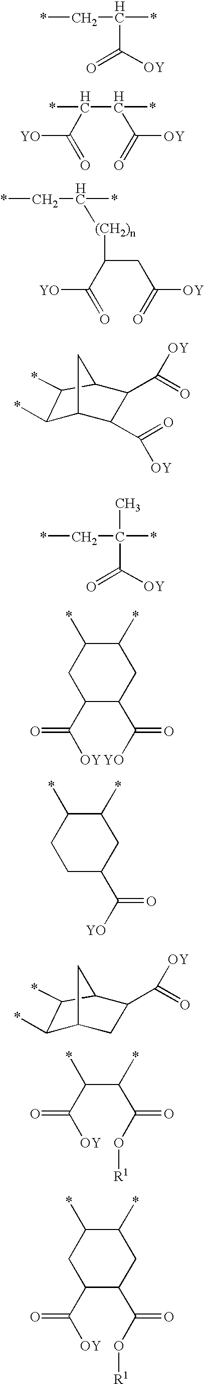

In order to coordinate the amplifying agent to the acidic groups of the film-forming polymer, this polymer must contain a basic group. An example of a suitable basic group is the amino group. The amplifying agent is preferably a silicon compound with basic functionalization, especially an aminosiloxane. Catenated dimethylsiloxanes having terminal aminopropyl units and from 2 to 51, preferably from 2 to 12 silicon atoms per molecule have been found particularly appropriate. A catenated dimethylsiloxane of this kind is shown below with its general structural formula.

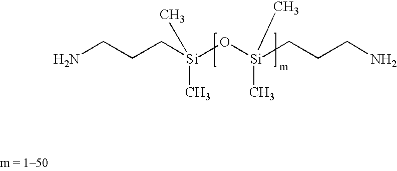

Further examples of amplifying agents containing amino-functional groups can be depicted by the following general structural formula:

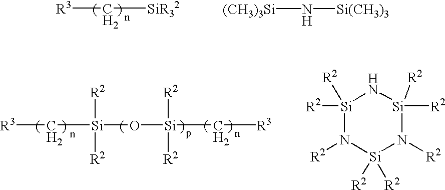

where R²═H, alkyl, aryl;

and R³═

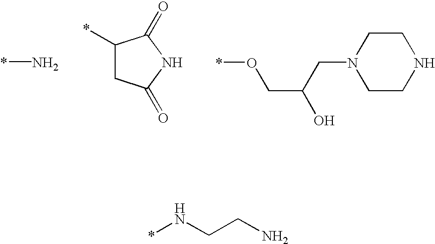

Besides basic amplifying agents containing silicon, other basic compounds are also suitable for carrying out the process of the invention. These compounds preferably contain aromatic groups, since this increases the resistance of the amplified resist toward an etching plasma. A number of suitable amplifying agents are given by way of example below:

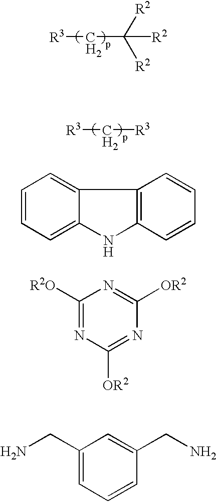

where the radicals R² and R³ are independent of one another and are as defined above, and p is from 0 to 30.

In a second embodiment, the anchor group is a Brönsted base and the amplifying agent is a Brönsted acid. The anchor group is preferably an amino group which may also have been protected with an acid-labile group, such as a tert-butylcarboxy group. Suitable monomer units containing a basic anchor group are depicted below:

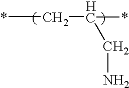

In the case of the second embodiment the amplifying agent must be a Brönsted acid. Suitable amplifying agents are depicted below:

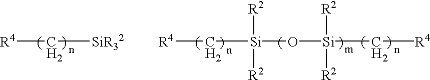

where R²═H, alkyl or aryl and R⁴═—H, —COOH, —SO₃H

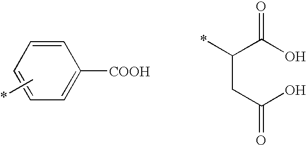

Where the film-forming polymer already contains acidic or basic groups which allow reaction with the amplifying agent, the amplification reaction can be carried out directly following the development of the resist. In general, however, the acidic and basic groups in the film-forming polymer that are needed for the amplification reaction are in a protected form. Following the development of the resist, therefore, these groups must first of all be released in the structured resist that remains on the substrate. As already mentioned, a variety of processes are possible for this purpose.

In accordance with a first process variant, the structured resist is subjected to flood exposure and then heated. As a result of flood exposure, acid is released from the photoacid generator in the hitherto unexposed areas of the photoresist as well. On subsequent heating at temperatures of, for example, from 60 to 170° C., the acid-labile groups on the polymer are eliminated and the acidic or basic groups required for coordination of the amplifying agent are released.

In accordance with a second process variant, the resist includes a thermoacid generator which releases an acid at a second temperature which is higher than the first temperature. The thermoacid generator is selected such that it remains substantially stable at temperatures which are reached when the solvent is evaporated following the application of the resist layer, or at the first temperature used in the PEB step. The release of the acid from the thermoacid generator takes place in general at temperatures from 80 to 200° C. Examples of suitable thermoacid generators include benzylthiolanium compounds. In this case as well, following elimination of the acid-labile groups, acidic or basic groups are available in the film-forming polymer and the amplifying agent can be coordinated to them.

The amplifying agent can be deposited on the resist from the gas phase. Preferably, however, the amplifying agent is applied to the resist in the form of the solution. The solvent must be able to dissolve the amplifying agent or to form an emulsion with it. The photoresist must be insoluble or only sparingly soluble in the solvent. It is nevertheless desirable for the solvent to swell the photoresist, so that the amplifying agent is able to diffuse even into relatively deep layers of the photoresist and bring about amplification there. Where the photoresist is insoluble in the solvent used for amplification, corresponding swelling promoters can be used. These are polar compounds of low molecular mass, such as water, for example, and lower alcohols, such as methanol or ethanol, or else low molecular mass ketones, such as acetone, for example.

With the process described above, a resist structure of increased etch resistance can be produced on a substrate. The invention also provides a process for structuring substrates for microelectronic circuits, in which a resist is applied to the substrate, structured, and amplified by the process described above, and then the substrate is etched.

Substrates which can be used are those which are customary for the manufacture of microchips, examples being silicon wafers. The substrates may also already include electronic components and the substrate may also include a plurality of resist layers.

In accordance with one preferred embodiment, the resist is amplified with a silicon-containing amplifying agent and the substrate is etched with an oxygen plasma.

The invention is illustrated with reference to an example.

A solution of a siloxane, grafted with polymethacrylic acid, in methoxypropyl acetate was applied to a wafer and dried at 130° C. The polymer therefore contains only carboxylic acid functional groups for silylation. The 200-nm polymer layer exhibits an increase in layer thickness of 50 nm in 30 seconds in the subsequent silylating test with an alcoholic aminosiloxane solution such as is already used in DRAM production. The siloxane solution contained 3% by weight of a bis-aminopropyl-functionalized oligodimethylsiloxane, 1% by weight of water, and hexanol as solvent.

A resist containing maleic anhydride was decomposed with water at 70° C. for 3 days. The completeness of the reaction was checked by IR measurements. A 200-nm layer of this reacted resist gives a layer thickness increase of 200 nm in 5 seconds with the same alcoholic aminosiloxane solution.

In both cases, only the free carboxylic acids in the polymer/resist act as anchors for the silylation in the neutralization reaction.

We claim:

1. A process for consolidating resist structures, which comprises:
(a) providing a chemically amplified resist including:
a polymer including acid-labile groups which on exposure to an acid are eliminated and release a group that results in an increase in a solubility of the polymer in aqueous alkaline developers, the polymer further including at least one anchor group for coordinating amplifying agents,
a photoacid generator, and
a solvent;
(b) applying the chemically amplified resist to a substrate;
(c) drying the resist to give a dried resist;
(d) exposing the dried resist to obtain an exposed resist that contains a latent image;
(e) heating the exposed resist to a first temperature such that the latent image is transformed into a chemical profile;
(f) developing the resist with an aqueous alkaline developer such that areas formed by the chemical profile are detached from the substrate and such that a structured resist is obtained;
(g) applying an amplifying agent to the structured resist; and
(h) washing off excess amplifying agent;
the amplifying agent and the anchor group each including a group selected from the group consisting of a polar group and an ionic group, and the coordination of the amplifying agent onto the anchor group taking place by forming a noncovalent bond.

2. The process according to claim 1, wherein:
the at least one anchor group is a protected anchor group including a first anchor group; and
before, performing step (g), the first anchor group is released from the protected anchor group;

3. The process according to claim 1, wherein:
the amplifying agent and the anchor group form an acid-base pairing and the amplifying agent is coordinated to the anchor group by forming a salt through an acid-base reaction.

4. The process according to claim 3, wherein the anchor group is a Brönsted base and the amplifying agent is a Brönsted acid.

5. The process according to claim 4, wherein the anchor group is an amino group that is protected by an acid-labile group.

6. The process according to claim 3, wherein the anchor group is a Brönsted acid and the amplifying agent is a Brönsted base.

7. The process according to claim 1, wherein the anchor group is a Brönsted acid and the amplifying agent is a Brönsted base.

8. The process according to claim 7, wherein the anchor group is selected from the group consisting of a carboxyl group, a sulfonic acid group, an acidic phenolic hydroxyl group and an acidic alcoholic hydroxyl group.

9. The process according to claim 3, wherein the amplifying agent is a silicon compound with a basic functionalization.

10. The process according to claim 9, wherein the amplifying agent is aminosiloxane.

11. The process according to claim 1, wherein the anchor group is a Brönsted base and the amplifying agent is a Brönsted acid.

12. The process according to claim 11, wherein the anchor group is an amino group.

13. The process according to claim 12, wherein the amino group is protected by an acid-labile group.

14. The process according to claim 1, which comprises:
applying the amplifying agent, as a solution, to the structured resist.

15. The process according to claim 1, which comprises:
subjecting the structured resist to flood exposure and then heating the structured resist.

16. The process according to claim 1, which comprises:
providing the resist with a thermoacid generator releasing an acid at a second temperature being higher than the first temperature; and
heating the structured resist to the second temperature.

17. A process for structuring a substrate for a microelectronic circuit, which comprises:
(a) providing a chemically amplified resist including:
a polymer including acid-labile groups which on exposure to an acid are eliminated and release a group that results in an increase in a solubility of the polymer in aqueous alkaline developers, the polymer further including at least one anchor group for coordinating amplifying agents,
a photoacid generator, and
a solvent;
(b) applying the chemically amplified resist to the substrate;
(c) drying the resist to give a dried resist;
(d) exposing the dried resist to obtain an exposed resist that contains a latent image;
(e) heating the exposed resist to a first temperature such that the latent image is transformed into a chemical profile;
(f) developing the resist with an aqueous alkaline developer such that areas formed by the chemical profile are detached from the substrate and such that a structured resist is obtained;
(g) applying an amplifying agent to the structured resist;
(h) washing off excess amplifying agent; and
(i) then etching the substrate;
the amplifying agent and the anchor group each including a group selected from the group consisting of a polar group and an ionic group, and the coordination of the amplifying agent onto the anchor group taking place by forming a noncovalent bond.

18. The process according to claim 17, which comprises:
amplifying the resist with a silicon-containing amplifying agent; and
performing the step of etching the substrate using an oxygen plasma.
